(19) United States
(12) Patent Application Publication
(10) Pub. No.: US 2024/0405582 A1
(43) Pub. Date: Dec. 5, 2024

(54) METHOD AND SOFTWARE FOR MANAGING ELECTRICAL ENERGY STORED IN A BATTERY

(71) Applicant: ENERGY S.p.A, Trento (IT)

(72) Inventors: Andrea TAFFURELLI, Padova (IT); Davide TINAZZI, Verona (IT)

(21) Appl. No.: 18/676,192

(22) Filed: May 28, 2024

(30) Foreign Application Priority Data
May 29, 2023 (IT) 102023000010779

(51) Int. Cl. H02J 7/00; H02J 3/28

(52) U.S. Cl. CPC H02J 7/0048; H02J 3/28; H02J 7/0014; H02J 7/007182

(57) ABSTRACT

An electrical energy management method for storage systems connectable to the electrical grid, comprising a first verification cycle for verifying the state of charge of a storage system, comprising
measuring the maximum state of charge in a predefined moment in time;
verifying whether the measured maximum state of charge (SOCril) is greater or less than a predefined value of the maximum state of charge (SOC_MAX);
if the measured maximum state of charge (SOCril) is less than said predefined value of the maximum state of charge (SOC_MAX), verifying for how long it has been less;
if it has been less for a period of time exceeding a predefined time interval, modifying a usage value of the minimum state of charge (SOC_MIN) of the storage system.

### TECHNICAL FIELD

The present invention relates to an electrical energy management method and software for storage systems.

In particular, the present invention fits into the field of energy management system (EMS) software applications that control and monitor storage systems in the private, commercial, and industrial sectors.

### PRIOR ART

On the market at present there are countless EMS platforms for the energy management of storage systems, preferably applied to photovoltaic systems for electricity production 2. In particular, in this sector, there are known highly advanced platforms for the management of residential, commercial, and industrial storage systems, also ones capable of managing very large amounts of data traffic.

In particular, although the major manufacturers of storage systems provide control systems for managing batteries and measuring parameters in order to verify correct operation, there are no known control strategies sufficiently accurate for storage systems.

In detail, as it is known that battery performance declines as a result of prolonged use, it is necessary to efficiently monitor the correct operation of batteries, and in particular, the charging and discharging cycles thereof.

### OBJECTS OF THE PRESENT INVENTION

In this situation, the object of the present invention is to provide an electrical energy management method and software for storage systems which remedies the aforementioned drawbacks.

In general, it is an object of the present invention to provide an electrical energy management method and software for storage systems which makes it possible to increase the life of the storage system/battery and the state of health (SOH) of the storage system itself.

It is in particular an object of the present invention to provide an electrical energy management method and software for storage systems that makes it possible to provide a more efficient control of the values of the storage system.

It is a further object of the present invention to provide an electrical energy management method and software for storage systems that makes it possible to optimise the operation of the storage system.

The specified objects are substantially achieved by an electrical energy management method and software for storage systems according to what is described in the appended claims.

### BRIEF DESCRIPTION OF THE FIGURES

Additional features and advantages of the present invention will become more apparent from the detailed description of some preferred, but non-exclusive embodiments of an electrical energy management method and software for storage systems illustrated in the appended drawings, in which:

FIG. 1 shows, in a schematic view, an example of application of the control method according to the present invention;

FIG. 2 shows a control scheme according to the method of the present invention.

### DETAILED DESCRIPTION OF ONE OR MORE PREFERRED EMBODIMENTS ACCORDING TO THE PRESENT INVENTION

With reference to the aforesaid figures, the reference number 1 denotes in its entirety a storage system controlled by means of the method according to the present invention.

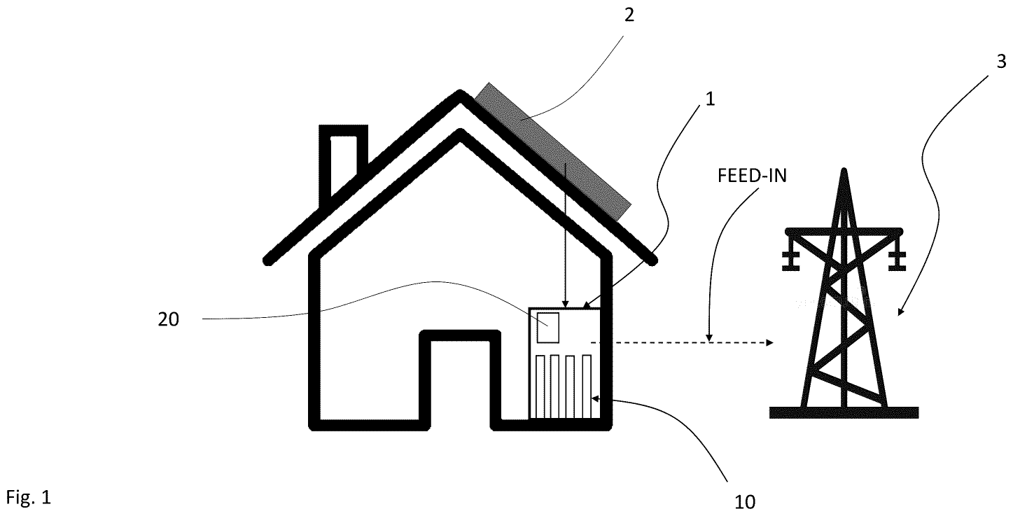

In particular, in FIG. 1 it is possible to see a schematically illustrated storage system 1 connected to a photovoltaic system 2, which supplies energy to recharge the batteries, and to the electrical grid 3 to feed electrical energy towards the grid.

However, it should be noted that the present invention is described and protected as such and thus not necessarily connected to a photovoltaic system 2. Therefore, the latter application of the invention must be considered only by way of non-exclusive example.

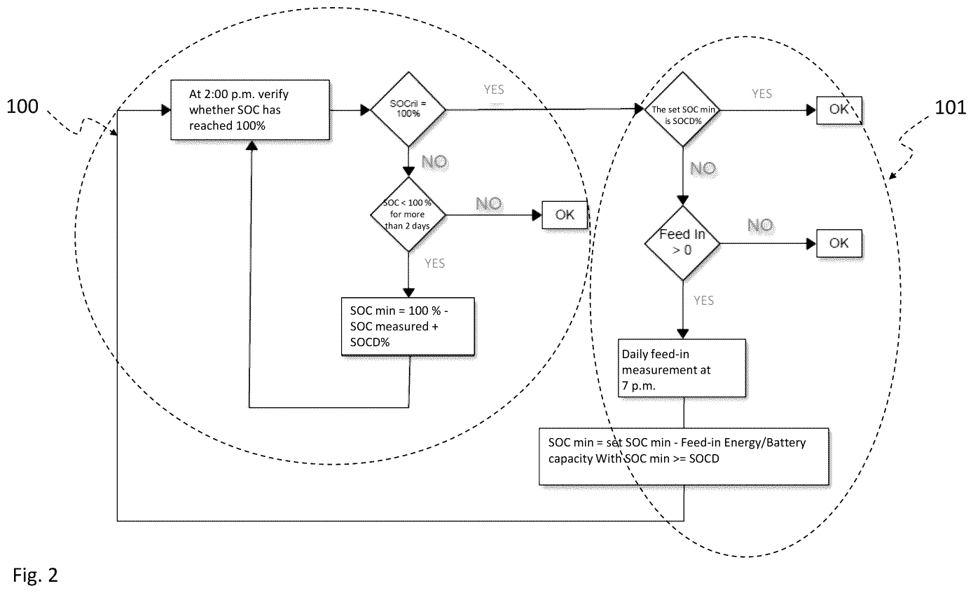

With reference to the following part of the description and, in particular, to the appended FIG. 2, it is necessary to explain the following meanings of the parameters that are taken into consideration:
H_CALC: Hour of the day in which the calculation is performed (parameter that can be set by the user);
N_DAYS: Days on which to verify the lack of a full charge (parameter that can be set by the user);
BATT_KWH: Capacity of the storage system 1 measured in kwh;
PERC_DEV: Percentage of deviation accepted;
SOC_MIN: Usage value of the minimum state of charge;
SOC_MAX: Predefined value of the maximum state of charge;
SOC_ril: Measured value of the maximum state of charge;
SOCD=Default value of the minimum state of charge, i.e. the value below which one must never go.

With particular reference to FIG. 2, the electrical energy management method comprises a first verification cycle 100 for verifying the state of charge of a storage system 1, wherein said first verification cycle 100 comprises the following operating steps:
measuring the maximum state of charge SOCril at a predefined moment in time H_CALC;
verifying whether the measured maximum state of charge SOCril is greater or less a predefined value of the maximum state of charge SOC_MAX;
if the measured maximum state of charge SOCril is less than said predefined value of the maximum state of charge SOC_MAX, verifying for how long it has been less;
if it has been greater for a period of time exceeding a predefined time interval, not modifying a usage value of the minimum state of charge SOC_MIN;
if it has been less for a period of time exceeding a predefined time interval, modifying a usage value of the minimum state of charge SOC_MIN of the storage system 1 according to the following formula:

Usage value of the minimum state of charge SOC_MIN=Predefined value of the maximum state of charge SOC_MAX−measured value of the maximum state of charge SOCril+Default value of the minimum state of charge SOCD.

In FIG. 2 it is assumed that the measured maximum state of charge SOCril is 100%, assuming a storage system 1 at the maximum of its capacities.

Furthermore, again in FIG. 2, it is assumed that the predefined time interval is two days (2 d).

It should be noted that the measurement of the maximum state of charge SOCril is performed every day in a same predefined time interval, preferably at the same hour.

Furthermore, the first verification cycle 100 is carried out every day in a same predefined time interval, preferably at the same hour.

For example, in FIG. 2 the first verification cycle 100 is carried out at 2:00 p.m. every day.

Preferably, the measurement of the maximum state of charge SOCril is performed at every predefined time interval (e.g. every minute) and the method envisages checking and possibly saving the values of the maximum state of charge SOCril and minimum state of charge SOC_MIN and an electrical energy FEED-IN value in a specific memory module.

At the set hour (H_CALC), the algorithm according to the present method checks the last N_DAYS of the saved array of daily values of the maximum state of charge. If all the values are less than the difference between the measured maximum state of charge SOCril and the percentage of accepted deviation PERC_DEV, the method calculates by how much to raise the usage value of the minimum state of charge SOC_MIN.

The usage value of the minimum state of charge SOC_MIN is raised by the difference between the maximum design state of charge SOC_MAX and the measured maximum state of charge SOCril reached on the last day considered.

If the measured value of the maximum state of charge SOCril is greater than or equal to said predefined value of the maximum state of charge SOC_MAX, the method envisages comparing the usage value of the minimum state of charge SOC_MIN of the storage system 1 with a default value of the minimum state of charge SOCD of the storage system 1.

If it emerges, from the comparison between the usage value of the minimum state of charge SOC_MIN of the storage system 1 and the default value of the minimum state of charge SOCD of the storage system 1, that the usage value of the minimum state of charge SOC_MIN is greater than the default value of the minimum state of charge SOCD, the following steps are performed (comprised in a second verification cycle 101):
checking a value of electrical energy FEED-IN towards an external electrical grid 3;
if that value of electrical energy FEED-IN is greater than zero, recalculating the usage value of the minimum state of charge SOC_MIN according to the following formula:

Usage value of the minimum state of charge SOC_MIN=Default value of the minimum state of charge SOCD−(electrical energy FEED-IN value/value of the battery storage capacity BATT_KWH).

If, by contrast, the calculated usage value of the minimum state of charge SOC_MIN is greater than or equal to the default value of the minimum state of charge SOCD, emitting a signal of correct status of the storage system 1. If the calculated usage value of the minimum state of charge SOC_MIN is less than the default value of the minimum state of charge SOCD, emitting a signal of poor status of the storage system 1.

In other words, if on the last day the design value of the maximum state of charge SOC_MAX was not reached correctly and the minimum usage value of the state of charge SOC_MIN was raised, the algorithm will recalculate it as a function of the ratio between the electrical energy FEED-IN value of the last 24 hours and the battery capacity BATT_KWH, subtracting the resulting value from the calculated usage value of the minimum state of charge SOC_MIN.

Advantageously, in this manner the batteries of the storage system are made to work towards the height of their capacity according to the availability of energy, thereby improving performance and the useful life.

A numerical example is given below:
SOC_MAX=90 [%]
PERC_DEV=10 [%]
N_DAYS=7
SOCD=20 [%]
SOC_MIN=20 [%]
BATT_KWH=100 [kWh]
H_CALC=14:00

The method monitors the maximum and minimum values of the state of charge every day and puts them in an array. The value N_DAYS being set at seven, we will have arrays with seven values of the measured maximum state of charge SOCril with which to carry out checks at the pre-established hour (in this example at 2:00 p.m.).

Three different arrays of measurements of the measured maximum state of charge SOCril are used as an example, namely:
A1=[85, 84, 83, 89, 81, 80, 82]
A2=[85, 75, 76, 78, 70, 60, 20]
A3=[72, 70, 65, 50, 55, 79, 72]

### FIRST EXAMPLE (A1)

2:00 p.m.->All the values are greater than SOC_MAX−PERC_DEV, i.e. 80%; therefore, the system is OK. SOC_MIN coincides with SOCD, so the values are correct.

### SECOND EXAMPLE (A2)

2:00 p.m.->One measured value is greater than SOC_MAX−PERC_DEV, i.e. 80%; therefore, the system is OK.

SOC_MIN coincides with SOCD, so the values are correct.

### THIRD EXAMPLE (A3)

2:00 p.m.->All the values of SOC_MAX are lower than 80%; therefore, it is necessary to recalculate SOC_MIN.

SOC_MIN=SOCD+(SOC_MAX−SOCril)=20+(90−79)=31 [%]

As SOC_MIN has been modified, it is not necessary to perform other verifications.

The next day at 2:00 p.m., everything remains unchanged, but SOC_MIN is greater than SOCD and it is thus necessary to check the FEED-IN. If the FEED-IN is zero, it means that the system is OK.

If the feed-in increases to 200 kWh, it will be necessary to recalculate SOC_MIN as:

SOC_MIN=SOC_MIN−(FEED_IN/BATT_kWh)=31−(200/100)=29[%],

which is a value greater than SOCD and thus accepted.

Furthermore, the present method envisages that said first verification cycle 100 for verifying the state of charge and/or said second verification cycle 101 for verifying the state of charge are carried out for every cell of the storage system 1. Therefore, N verification cycles will be carried out, depending on the number of cells of the storage system 1.

In addition, the method envisages a further step of checking the electrical voltage of each cell of the storage system 1, which comprises performing the following sub-steps:
detecting the cell having a higher value of electrical voltage than the other cells of the same storage system 1,
detecting the cell having a lower value of electrical voltage than the other cells of the same storage system 1;
calculating the difference between said higher value of electrical voltage and said lower value of electrical voltage.

In addition, the method envisages verifying:
whether the difference between said higher value of electrical voltage and said lower value of electrical voltage is less than a predefined range of values; if so, the system is OK;
whether the difference between said value of electrical voltage is greater and said lower value of electrical voltage value is greater than a predefined range of values;
if said difference is greater than said predefined range of values, carrying out a balancing step; said balancing step envisages maintaining the storage system (1) at a constant voltage for a certain period of time until reaching a predefined balancing state.

For example, if the cell with the highest voltage exceeds 3.36 V, and the difference between the cell with the highest voltage and the one with the lowest voltage is less than 50 mV (predefined range of values), then the system is balanced.

If the difference between the cell with the highest voltage and the one with the lowest voltage is greater than 50 mV, the method envisages carrying out a balancing step, which will maintain the system at a constant voltage for a certain period of time until it reaches a balanced state.

The “balanced state” or “balancing” corresponds to a state in which all the cells are maintained at a constant voltage or, at most, show differences between them which are lower than a predefined range of values.

If the cell with the highest voltage is below 3.36 V, and the difference between the cell with the highest voltage and the one with the lowest voltage is less than 30 mV, then the system is balanced. If, by contrast, that difference is greater than 30 mV, it goes into the balancing mode, which will maintain the system at a constant voltage for a certain period of time until it reaches a balanced state.

Advantageously the present invention enables the detection of an “unbalanced state” of voltage of the cells which corresponds to the amount by which the maximum voltage difference between the cells is greater than a predefined value.

The method envisages that, when an unbalanced state occurs, the use of the storage system/battery will be interrupted and a rebalancing step will be carried out which consists in a controlled recharging of the battery itself in order to rebalance the cells immediately and prevent them from deteriorating.

In other words, the rebalancing step is a recharging with an optimal current determined by a battery management system (BMS) module which provides for a realignment of the voltages of the various cells. In fact, it is not possible to recharge the cells individually, but as they are in series the current will flow through all of them equally, recharging and rebalancing them.

The subject matter of the present invention further relates to electrical energy management software for storage systems connectable to the electrical grid 3, which derives directly from what was illustrated above in relation to the method, which is entirely referenced here below.

The software envisages carrying out the above-described steps of the method by means of a processing unit.

In addition, the present invention relates to an electrical energy storage system 1 comprising:
a plurality of storage batteries 10 (defining said storage system 1 at least in part);
a processing unit 20 configured to execute the electrical energy management software described above.

Optionally, the storage batteries 10 can be connected to a photovoltaic system 2 in order to receive recharging energy from the latter.

Furthermore, preferably the storage batteries 10 can be connected to an external electrical grid 3 in order to deliver FEED-IN electrical energy towards the outside.

The present invention achieves the proposed objects.

First of all, thanks to the presence of the control method, it is possible to monitor the state of charge/discharge of the storage system in order to maintain values that enable an optimal equalisation of the cells and a state of charge (SOC) such as to maintain a good state of health (SOH) of the batteries.

Furthermore, the implementation of the method is not tied to system alarms or protection states, which can compromise the normal operation of the equipment with interruptions or de-rating of the service, but rather to strategies adapted to prevent potential failures and above all to improve the natural decay of lithium batteries.

It is thus a set of operations implemented at times and in ways that do not overlap with or undermine the normal operation of the system.

1. An electrical energy management method for storage systems connectable to an electrical grid, comprising a first verification cycle for verifying a state of charge of a storage system, wherein said first verification cycle comprises:
measuring a maximum state of charge (SOCril) at a predefined moment in time;
if the measured maximum state of charge (SOCril) is less than a predefined value of the maximum state of charge (SOC_MAX), determining how long the maximum state of charge (SOCril) has been less than the predefined value of the maximum state of charge (SOC_MAX);
if the maximum state of charge (SOCril) has been less for a period of time exceeding a predefined time interval, modifying a usage value of a minimum state of charge (SOC_MIN) of the storage system according to the following formula:
The usage value of the minimum state of charge (SOC_MIN)=the predefined value of the maximum state of charge (SOC_MAX)−the measured value of the maximum state of charge (SOCril)+a default value of the minimum state of charge (SOCD);
wherein said default value of the minimum state of charge (SOCD) is a default value of the minimum state of charge defined as per design;
if the measured value of the maximum state of charge (SOCril) is greater than or equal to said predefined value of the maximum state of charge (SOC_MAX), comparing the usage value of the minimum state of charge (SOC_MIN) of the storage system with a default value of the minimum state of charge (SOCD) of the storage system;
if, from the comparison between the usage value of the minimum state of charge (SOC_MIN) of the storage system and the default value of the minimum state of charge (SOCD) of the storage system, that the usage value of the minimum state of charge (SOC_MIN) is greater than the default value of the minimum state of charge (SOCD), a second verification cycle is performed comprising:
checking a value of an electrical energy feed-in (FEED-IN) towards an external electrical grid;
if the value of the electrical energy feed-in (FEED-IN) is greater than zero, recalculating the usage value of the minimum state of charge (SOC_MIN) according to the following formula:
The usage value of the minimum state of charge (SOC_MIN)=The default value of the minimum state of charge (SOCD)−(the value of the electrical energy feed-in (FEED-IN)/a value of a battery storage capacity (BATT_KWH));
if the calculated usage value of the minimum state of charge (SOC_MIN) is greater than or equal to the default value of the minimum state of charge (SOCD), emitting a signal of correct status of the storage system; and
if the calculated usage value of the minimum state of charge (SOC_MIN) is less than the default value of the minimum state of charge (SOCD), emitting a signal of poor status of the storage system.

2. The method according to claim 1, wherein the measurement of the maximum state of charge (SOCril) is performed every day in a same predefined time interval, within the same hour.

3. The method according to claim 1, wherein the first verification cycle is carried out every day in a same predefined time interval, within the same hour.

4. The method according to claim 1, wherein the said first verification cycle or said second verification cycle is carried out for every cell of the storage system.

5. The method according to claim 1, further comprising:
checking an electrical voltage of each cell of a plurality of cells of the storage system;
detecting a first cell of the plurality of cells having a higher value of electrical voltage than the other cells of the plurality of cells of the same storage system;
detecting a second cell of the plurality of cells having a lower value of electrical voltage than the other cells of the plurality of cells of the same storage system; and
calculating the difference between said higher value of electrical voltage and said lower value of electrical voltage.

6. The method according to claim 5, further comprising:
determining whether the difference between said higher value of electrical voltage and said lower value of electrical voltage is greater than a predefined range of values; and
if said difference is greater than said predefined range of values, carrying out a balancing step; said balancing step comprises maintaining the storage system at a constant voltage for a predefined period of time until reaching a predefined balancing state.

7. A non-transitory computer-readable storage medium having computer-readable program code corresponding to electrical energy management software for storage systems connectable to the electrical grid, the computer-readable program code executable by one or more computer processors to carry out the steps of the method according to claim 1.

8. An electrical energy storage system comprising:
a plurality of storage batteries; and
a processing unit configured to carry out the steps of the method according to claim 1.

9. The non-transitory computer-readable storage medium of claim 7, wherein the measurement of the maximum state of charge (SOCril) is performed every day in a same predefined time interval within the same hour.

10. The non-transitory computer-readable storage medium of claim 7, wherein the first verification cycle is carried out every day in a same predefined time interval within the same hour.

11. The non-transitory computer-readable storage medium of claim 7, wherein the said first verification cycle or said second verification cycle is carried out for every cell of the storage system.

12. The non-transitory computer-readable storage medium of claim 7, wherein the computer-readable program code is executable by one or more computer processors to:
check an electrical voltage of each cell of a plurality of cells of the storage system;
detecting a first cell of the plurality of cells having a higher value of electrical voltage than the other cells of the plurality of cells of the same storage system;
detect a second cell of the plurality of cells having a lower value of electrical voltage than the other cells of the plurality of cells of the same storage system; and
calculate the difference between said higher value of electrical voltage and said lower value of electrical voltage.

13. The non-transitory computer-readable storage medium of claim 12, wherein the computer-readable program code is executable by one or more computer processors to:
determine whether the difference between said higher value of electrical voltage and said lower value of electrical voltage is greater than a predefined range of values; and
if said difference is greater than said predefined range of values, carrying out a balancing step; said balancing step comprises maintaining the storage system at a constant voltage for a predefined period of time until reaching a predefined balancing state.

14. The electrical energy storage system of claim 8, wherein the measurement of the maximum state of charge (SOCril) is performed every day in a same predefined time interval within the same hour.

15. The electrical energy storage system of claim 8, wherein the first verification cycle is carried out every day in a same predefined time interval within the same hour.

16. The electrical energy storage system of claim 8, wherein the said first verification cycle or said second verification cycle is carried out for every cell of the storage system.

17. The electrical energy storage system of claim 8, wherein the processing unit is configured to:
check an electrical voltage of each cell of a plurality of cells of the storage system;
detecting a first cell of the plurality of cells having a higher value of electrical voltage than the other cells of the plurality of cells of the same storage system;
detect a second cell of the plurality of cells having a lower value of electrical voltage than the other cells of the plurality of cells of the same storage system; and
calculate the difference between said higher value of electrical voltage and said lower value of electrical voltage.

18. The electrical energy storage system of claim 17, wherein the processing unit is configured to:
determine whether the difference between said higher value of electrical voltage and said lower value of electrical voltage is greater than a predefined range of values; and
if said difference is greater than said predefined range of values, carrying out a balancing step; said balancing step comprises maintaining the storage system at a constant voltage for a predefined period of time until reaching a predefined balancing state.
